(19) United States
(12) Patent Application Publication
(10) Pub. No.: US 2023/0258710 A1
(43) Pub. Date: Aug. 17, 2023

(54) CHIP RELIABILITY TEST ASSEMBLY

(71) Applicant: Luxsentek Microelectronics Corp., New Taipei City (TW)

(72) Inventors: CHAO-YANG HSIAO, New Taipei City (TW); SHENG-CHENG LEE, New Taipei City (TW); WEN-SHENG LIN, New Taipei City (TW); CHIH-WEI LIN, New Taipei City (TW); CHEN-HUA HSI, New Taipei City (TW); YUEH-HUNG HO, New Taipei City (TW)

(21) Appl. No.: 17/836,744

(22) Filed: Jun. 9, 2022

(30) Foreign Application Priority Data
Feb. 14, 2022 (TW) 111105251

(51) Int. Cl. G01R 31/28

(52) U.S. Cl. CPC G01R 31/2863; G01R 31/2875

(57) ABSTRACT

The present invention proposes a chip reliability test assembly, which comprises a motherboard and a daughter board. The motherboard is used to support the chips during an aging acceleration process at high temperature. The daughter board is used to measure the electricity of chip after the aging acceleration process. Each chip holder is removable off the motherboard. The daughter board does not go through the aging acceleration process and can be reusable.

### BACKGROUND OF THE INVENTION

### 1. Field of the Invention

The present invention relates to a chip reliability test assembly, particularly a chip reliability test assembly including a motherboard with breakable chip holders and a reusable daughter board.

### 2. Description of the Prior Art

In generally, the reliability test is to verify the electrical properties of a chip through an aging acceleration process. The process uses a motherboard with a daughter board to carry chips and is exposed under a high temperature. After that, each daughter board must be stripped down from the motherboard one by one for the following verification process.

The daughter board cannot be reused due to high temperature baking, and it is inefficient due to one-by-one stripping steps.

### SUMMARY OF THE INVENTION

The chip reliability test assembly proposed by the present invention has the characteristics of reusability and high-efficiency electrical verification.

The motherboard of the present invention is used for carrying chips through an aging acceleration process. The daughter board is used to perform electrical verification on a plurality of chips at one time when connecting with the motherboard. The verification can be repeated. The invention can improve the verification efficiency.

The present invention provides a chip reliability test assembly. A motherboard has a plurality of test areas with the same geometric shape. Each test area includes a plurality of chip holders. Each chip holder is used to carry a chip and can be broken off and discarded. A daughter board, corresponding to the test areas, is used to verify the electrical properties of the chips in the test area.

In addition, the locking screw holes of the motherboard can be used as high temperature connection terminals.

### BRIEF DESCRIPTION OF THE DRAWINGS

FIG. 1 is a schematic diagram of the motherboard structure of the chip reliability test assembly of the present invention.

FIG. 2 is a schematic diagram of the combination of the motherboard and the daughter board of the present invention.

### DESCRIPTION OF THE PREFERRED EMBODIMENTS

Below embodiments accompanied with drawings are used to explain the spirit of this invention to have better understanding for the person in this art, not used to limit the scope of this invention, which is defined by the claims. The applicant emphasizes the element quantity and size are schematic only. Moreover, some parts might be omitted to skeletally represent this invention for conciseness.

The chip reliability test assembly of the present invention comprises a motherboard and a daughter board which are separated from each other. The motherboard has many holders for carrying chips to go through the aging acceleration process. After the aging acceleration process, the daughter board are connected to the motherboard to verify the electrical properties of the chips. This means that the daughter board is never baked under the high temperature environment and can be reused. Each chip holder can be stripped down. If the chip fails to test, the chip holder and the chip can be spilled off from the motherboard and be discarded.

Comparing with the conventional test assembly, the present test assembly is very efficient. The present test assembly is not necessary to remove the chips from the motherboard one by one for the electrical testing. In the present invention, a plurality of sensing pins on the daughter board can be plugged into the corresponding pinholes on the motherboard, and the chips can be verified at the same time. The present test assembly greatly improves the verification efficiency.

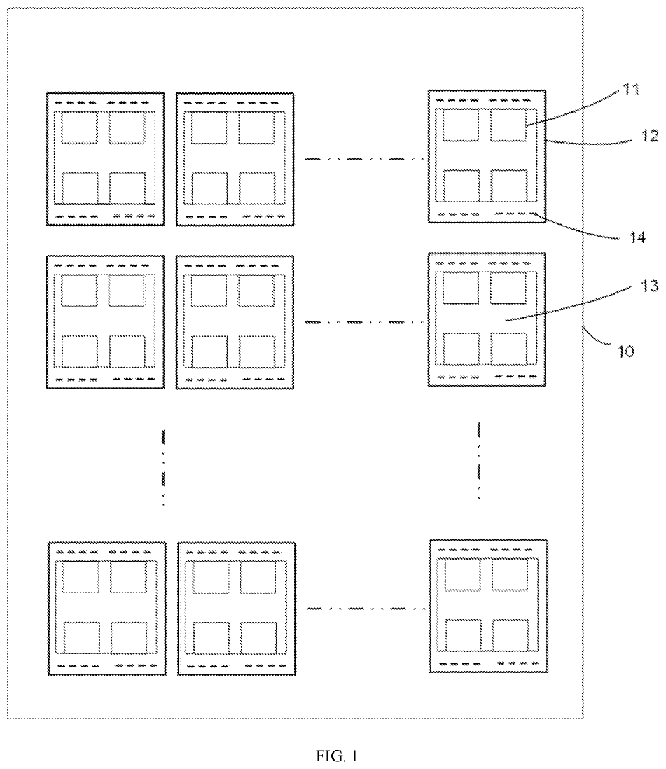

FIG. 1 illustrates a motherboard 10 of a chip reliability test assembly. The motherboard 10 has a plurality of test areas 12, each test area 12 includes a plurality of chip holders 11. Each chip holder 11 carries a chip. As shown as the figure, the test area 12 has four chip holders 11 and a hollow part 13 between the chip holders. Each of the chip holders 11 is independent. The sensing pinholes 14 around the test area 12 electrically connect with the chips on the chip holder 11.

It is noted that each chip holder 11 can be spilled off. In one embodiment, an easy-break line is set on the chip holder 11. The chip holder 11 can be easily broken off along the easy-break line. The test area 12 can be made in different geometric shapes, in one embodiment, it is designed to be a square. Another implementation may be designed to be a rectangle.

In addition, the motherboard is locked in an aging device (such as a baking box), and the motherboard is needed to connect an external power supply during the aging process in some embodiments. For example, one or more sets of power supply or ground connection terminals. In conventional test assemblies, the motherboard is disposed additionally the anti-high-temperature terminals, however the locking screw holes are used as the high temperature terminals to form a terminal-free chip reliability test assembly.

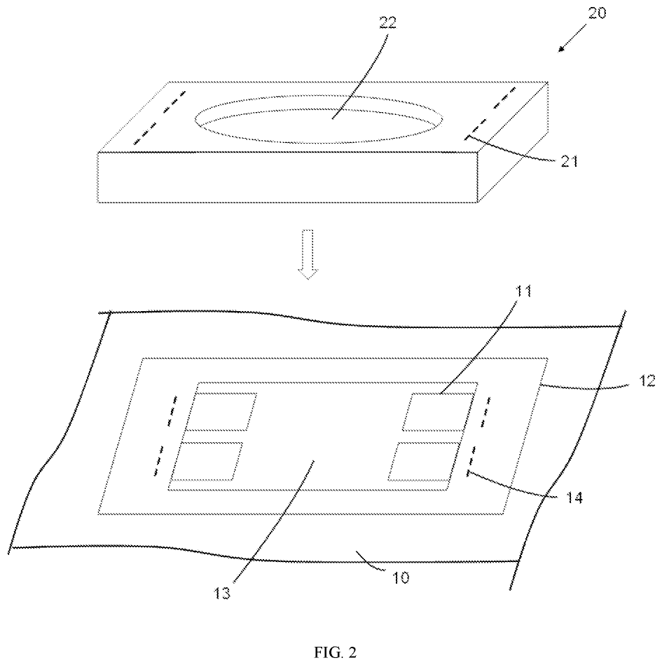

FIG. 2 shows the daughter board 20 on the top, and the motherboard 10 on the bottom. The daughter board 20 can be connected with the mother board 10 and the daughter board 20 for verifying the chips. First, a plurality of chips can be tested in verification process. Second, the chip holders are not needed to be removed from the motherboard 10 one by one, and instead the daughter board 20 is connected to the motherboard 10 to verify the chips and to enhance the efficiency. There are circuit terminals 21 on upper surface of the daughter board 20 for connecting to an external detection system. The sensing pins or sensing plugs (not shown in the figure) on the lower surface of the daughter board 20 are connected to the sensing pinholes 14 of the motherboard during the verification process. A through hole 22, at the center of the daughter board 20, can be used to do a light-sensing test, a sound-sensing test or a pressure-sensing test. For example, a special photosensitive test can be performed by installing an optical lens in the through hole 22.

The connection of the daughter board and the motherboard is mainly to achieve the function of electrical connection. For example, the motherboard is designed as a probe hole, and the daughter board is designed as a corresponding probe, or vice versa. In one embodiment, the motherboard and the daughter board are conducted through contact.

The shape of daughter board 20 is not limited but specialized to connect with a plurality of chip. In general, the geometric shape is corresponding to the test area of the motherboard 10, and it is used to verify a plurality of chips in one time.

It is easy to perform the reliability test by using the present test assembly. First, the motherboard with chips is placed in a baking box at high temperature for a period of time, i.e. the aging acceleration process. Next, the daughter is joined with the motherboard after cooling to test the electrical properties of chips, i.e. the verification process.

In addition, optical properties of the chip can be performed synchronously by installing an optical lens on the daughter board. The pressure-sensing tests or sound-sensing tests can be performed simultaneously by the similar way. For example, the through hole 22 is provided in the center of the daughter board 20 of the embodiment shown in FIG. 2, and an optical lens can be installed in the through hole 22 so that optical properties can be tested. Another embodiment is to pressurize through the through hole 22 to perform a pressure sensing test.

What is claimed is:

1. A chip reliability test assembly, comprising:
a motherboard used for an aging process, wherein the motherboard has a plurality of test areas, each test area includes a plurality of independent chip holders and each chip holder is used to carry a chip; and
a daughter board, corresponding to the test area, used to electrically connect to the test area to perform a test process.

2. The chip reliability test assembly according to claim 1, wherein the motherboard further includes a locking screw hole, and the locking screw hole is used as a high-temperature electrical connection terminal.

3. The chip reliability test assembly according to claim 1, wherein an easy-break line related to each chip holder is set, and the chip can be spilled off along the easy-break line.

4. The chip reliability test assembly according to claim 1, wherein a plurality of sensing pinholes is set around each test area, and the daughter board has a plurality of sensing pins corresponding the sensing pinholes for verifying the chips in the test area.

5. The chip reliability test assembly according to claim 1, wherein a shape of the test area is square.

6. The chip reliability test assembly according to claim 5, wherein the daughter board has a through hole at the center, and a light-sensing test, a sound-sensing test or a pressure-sensing test is performed on all the chips in the test area through the through hole.

7. A chip reliability test assembly, comprising:
a motherboard used for an aging process, wherein the motherboard has a plurality of independent chip holders, each chip holder is used to carry a chip and the chip holder can be spilled off; and
a daughter board used to perform a test process, wherein the daughter board can be electrically connected to all or part of the chips on the motherboard.

8. The chip reliability test assembly according to claim 7, wherein the motherboard includes a locking screw hole, which is used as a high-temperature electrical connection terminal.

9. The chip reliability test assembly according to claim 7, wherein a plurality of sensing pinholes is arranged around the chip holders, and the daughter board has a plurality of sensing pins that can be bonded to all or part of the plurality of sensing pinholes.

10. A method for testing chip reliability, comprising:
locking a motherboard in a baking box for an aging process, wherein the motherboard has a plurality of independent removable chip holders and each chip holder is used to carry a chip;
performing an aging acceleration on the motherboard in the baking box; and
combining a daughter board with the motherboard to verify a plurality of the chips at the same time.
